(19) United States
(12) Patent Application Publication
(10) Pub. No.: US 2019/0221502 A1
(43) Pub. Date: Jul. 18, 2019

(54) Down Bond in Semiconductor Devices

(71) Applicant: Microchip Technology Incorporated, Chandler, AZ (US)

(72) Inventors: Joseph Fernandez, Chachengsao (TH); Rangsun Kitnarong, Nonthaburi (TH); Tarapong Soontornvipart, Chachengsao (TH); Janwit Apirukaramwong, Ayuttahya (TH); Prachit Punyapor, Pathumtani (TH); Supakrits Suttiwat, Muang (TH); Ekgachai Kenganantanon, Nonthaburi (TH)

(73) Assignee: Microchip Technology Incorporated, Chandler, AZ (US)

(21) Appl. No.: 15/939,586

(22) Filed: Mar. 29, 2018

Related U.S. Application Data
(60) Provisional application No. 62/618,347, filed on Jan. 17, 2018.

(51) Int. Cl. H01L 23/495

(52) U.S. Cl. CPC H01L 23/4952; H01L 23/49575; H01L 23/49503

(57) ABSTRACT

An apparatus includes a lead frame paddle configured for mounting a semiconductor die. The apparatus further includes a plating area formed on the lead frame paddle. The plating area is configured to receive a down bond from a semiconductor die placed on the lead frame paddle. The apparatus further includes an exposed gap between an outer edge of the plating area and an outer edge of the lead frame paddle.

### APPLICATION PRIORITY

This application claims priority to U.S. Provisional Patent Application No. 62/618,347 filed Jan. 17, 2018, the contents of which are hereby incorporated in their entirety.

### FIELD OF THE INVENTION

The present disclosure relates to semiconductor fabrication and, more particularly, to a down bond in semiconductor devices for silver connections.

### BACKGROUND

Semiconductor devices, integrated circuits, systems-on-a-chip (SoC), and other electronic devices may be manufactured in a chip package. The chip package may include connections and structures to connect the semiconductor elements inside the package to other components inside the package and to external elements. In order to connect the semiconductor elements via leads, pins, die pads, and similar connections, a package may include a lead frame. A lead frame may be made from a thin layer of metal. A lead frame may include a pad or paddle onto which the semiconductor elements may be affixed. The semiconductor elements may rest on the pad or paddle of the lead frame.

Within the chip package, a variety of connections may be made to connect the various elements therein. Such connections may include wire bonds, down bonds, and epoxy.

Delamination is a condition that may affect connections within the chip package. Delamination may include a separation between two materials within a package. Delamination may lead to failures. Delamination in certain areas causes a reliability risk and may lead to other failures. Such other failures may include die corrosion, package cracking, bond lifting, and breaking of the neck or heel of a bond. Delamination may also lead to failures of the integrated circuit by shifting various operating parameters.

### SUMMARY

Embodiments of the present disclosure include an apparatus. The apparatus may include a lead frame paddle configured for mounting a semiconductor die. The apparatus may further include a plating area formed on the lead frame paddle. The plating area may be configured to receive a down bond from a semiconductor die placed on the lead frame paddle. The apparatus may include an exposed gap between an outer edge of the plating area and an outer edge of the lead frame paddle. In combination with any of the above embodiments, the plating area may be formed of silver. In combination with any of the above embodiments, the exposed gap may be formed of copper. In combination with any of the above embodiments, the plating area may be formed as a ring around a perimeter of the lead frame paddle. In combination with any of the above embodiments, the apparatus may further include a hollow portion within the plating area, wherein the hollow portion underlies the semiconductor die placed on the lead frame paddle. In combination with any of the above embodiments, the plating area may be formed as a rectangle on the lead frame paddle, the rectangle coextensive with a perimeter of the lead frame paddle. In combination with any of the above embodiments, the apparatus may further include additional plating areas, wherein each additional plating area includes a further exposed gap between an outer edge of the additional plating area and the outer edge of the lead frame paddle.

Embodiments of the present disclosure include an integrated circuit package. The integrated circuit package may include a lead frame paddle configured for mounting a semiconductor die. The integrated circuit package may further include a plating area formed on the lead frame paddle. The plating area may be configured to receive a down bond from a semiconductor die placed on the lead frame paddle. The integrated circuit package may include an exposed gap between an outer edge of the plating area and an outer edge of the lead frame paddle. In combination with any of the above embodiments, the plating area may be formed of silver. In combination with any of the above embodiments, the exposed gap may be formed of copper. In combination with any of the above embodiments, the plating area may be formed as a ring around a perimeter of the lead frame paddle. In combination with any of the above embodiments, the integrated circuit package may further include a hollow portion within the plating area, wherein the hollow portion underlies the semiconductor die placed on the lead frame paddle. In combination with any of the above embodiments, the plating area may be formed as a rectangle on the lead frame paddle, the rectangle coextensive with a perimeter of the lead frame paddle. In combination with any of the above embodiments, the integrated circuit package may further include additional plating areas, wherein each additional plating area includes a further exposed gap between an outer edge of the additional plating area and the outer edge of the lead frame paddle.

Embodiments of the present disclosure may include methods for forming or building any of the apparatuses or integrated circuit packages described above. The method may include forming a lead frame paddle, forming a plating area on the lead frame paddle, and forming an exposed gap between an outer edge of the plating area and an outer edge of the lead frame paddle. In combination with any of the above embodiments, the method may include mounting a semiconductor device on the lead frame paddle. In combination with any of the above embodiments, the method may include forming a down bond from the semiconductor die to the plating area. In combination with any of the above embodiments, the plating area may be formed of silver. In combination with any of the above embodiments, the exposed gap may be formed of copper. In combination with any of the above embodiments, the method may include forming the plating area as a ring around a perimeter of the lead frame paddle. In combination with any of the above embodiments, the method may include forming the plating area as a rectangle on the lead frame paddle, the rectangle coextensive with a perimeter of the lead frame paddle. In combination with any of the above embodiments, the method may include forming additional plating areas on the lead frame paddle, wherein each additional plating area includes a further exposed gap between an outer edge of the additional plating area and the outer edge of the lead frame paddle. In combination with any of the above embodiments, the method may include forming a down bond from the semiconductor die to each of the additional plating areas.

### BRIEF DESCRIPTION OF THE DRAWINGS

FIG. 1 is an illustration of an example chip package, according to embodiments of the present disclosure

FIG. 2 is an illustration of a chip package with delamination.

FIG. 3 is a top-view of a chip package with a ring of silver in the lead frame, according to embodiments of the present disclosure.

FIG. 4 is a top-view of a chip package with isolated silver or silver islands in the lead frame, according to embodiments of the present disclosure.

FIG. 5 is a top-view of a chip package with rectangular silver plating area in the lead frame, according to embodiments of the present disclosure.

FIG. 6 illustrates a chip package without gaps between a plating area and an edge of a lead frame paddle.

### DETAILED DESCRIPTION

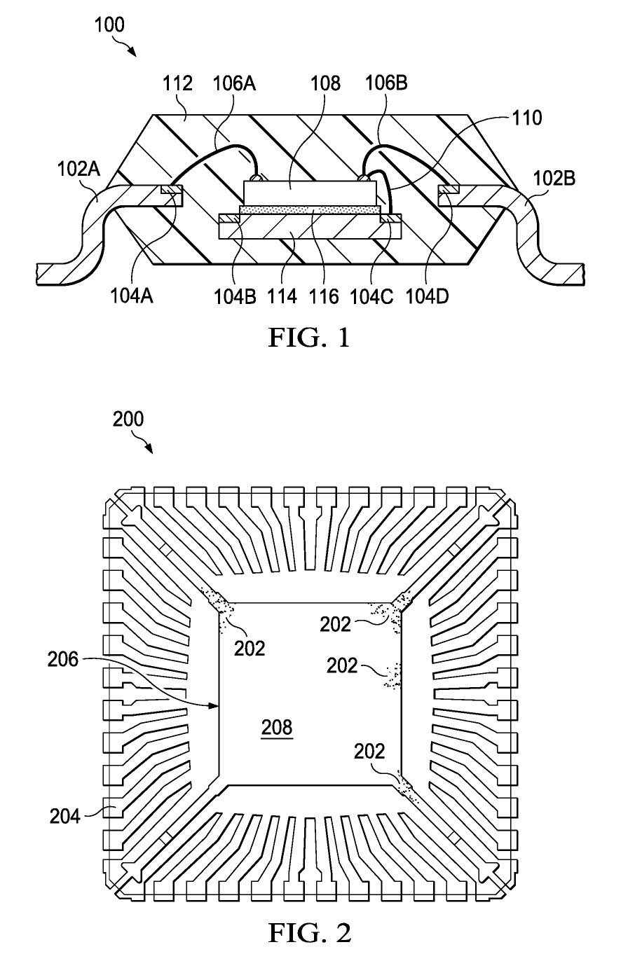

FIG. 1 is an illustration of an example chip package 100, according to embodiments of the present disclosure. FIG. 1 illustrates a side view of the example chip package 100. Chip package 100 may include packaging for any suitable integrated circuit.

Chip package 100 may include a semiconductor die 108 implementing a semiconductor element. Semiconductor die 108 may be mounted onto a lead frame pad or paddle 114. Semiconductor die 108 may be mounted onto a lead frame pad or paddle 114 using an epoxy or die attach 116.

Semiconductor die 108 may include several options for connecting to a lead frame arm 102 and to lead frame pad or paddle 114. To connect semiconductor die 108 to lead frame arm 102, a wire bond 106 may be used. To connect semiconductor die 108 to lead frame pad or paddle 114, a down bond 110 may be used. The lead frame may include metal areas for making attachments to semiconductor die 108. Such metal areas may include silver 104. Although silver is used as an example in the present disclosure, other suitable metals for a plating area may be used. Semiconductor die and its connections may be encapsulated in a mold 112. Lead frame arm 102 and lead frame pad or paddle 114 may be made from copper or another suitable metal.

In semiconductor device manufacture, delamination might not be allowed on down bonds 110 of wire bonding. Particularly, delamination might not be allowed on down bonds 110 in wire bonding on active areas on lead frame paddle or pad 114 of chip devices such as chip package 100. Delamination may be measured from pre-moisture soak to post-reflow per moisture sensitivity level conditions.

Delamination may particularly arise when semiconductor die 208 is of a large size and silver connection areas 104 are limited. During manufacture, adhesion may be poor between the molding compound of mold 112 and limited silver connection areas 104 around lead frame pad or paddle 114 for down bonding 110. Thus, delamination may exist around semiconductor die 108 or lead frame pad or paddle 114. Removal or prevention of delamination may result in good adhesion between copper areas and molding material of mold 112.

Delamination may cause unreliable product quality. It may be costly to use additional baking and dry packing processes to remove moisture from chip package 100, which may be required if delamination occurs.

FIG. 2 is an illustration of a chip package 200 with delamination. Chip package may include numerous lead frame arms 204, a lead frame pad or paddle 206, and a semiconductor die 208. Delamination 202 may form on down bonds of wire bonding (not shown).

Returning to FIG. 1, embodiments of the present disclosure may improve adhesion to silver surfaces 104 of the lead frame. In particular, adhesion may be improved at a location where a down bond is affixed in place in molding compound, such as down bond 110 to silver surface 104C. Delamination may be resolved and moisture sensitivity levels (MSLs) of leaded integrated circuit packages according to standards, such as JEDEC J-STD-020, may achieved.

In one embodiment, position of silver layers 104 on lead frame pad or paddle 114 may be established set to avoid problems of delamination. In another embodiment, lead frame pad or paddle 114 may include a copper layer on its top surface, the copper layer horizontally separating silver layers 104 from an edge of lead frame pad or paddle 114. Silver layers 104 may be where a portion of a top of semiconductor die 108 is down-bonded to lead frame pad or paddle 114. This may improve product quality and reliability to prevent lifted bonds resulting from the delamination at down bonding areas on lead frame paddles. This delamination affects the moisture absorption during the flow soldering process, which may be performed during affixation of semiconductor devices or during reliability tests.

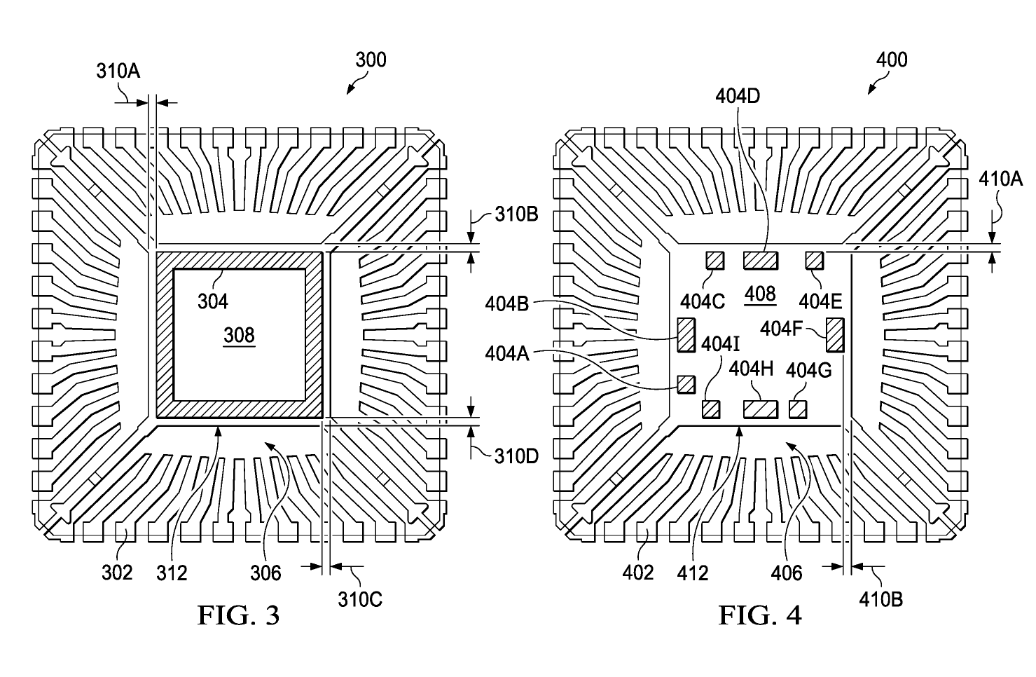

FIGS. 3-5 illustrate example embodiments of the present disclosure wherein a copper layer separates silver layers from an outer edge of a lead frame pad or paddle. The separation may include a copper metal layer. Each of the examples of FIGS. 3-5 may utilize different arrangements of silver. Elements other than arrangements of silver may be similarly configured between the examples of FIGS. 3-5. The copper layer may be implemented as a gap or separation between a plating area and an outer edge of a lead frame pad or paddle. The copper layer may be the same width on all sides of the lead frame pad or paddle with respect to the outer edge of any plating areas.

FIG. 3 is a top-view of a chip package 300 with a ring of silver in the lead frame, according to embodiments of the present disclosure.

Chip package 300 may include a lead frame paddle or pad 312. Lead frame paddle or pad 312 may be implemented using any suitable metal, such as copper. Lead frame paddle or pad 312 may include four angled support arms extending from corners of chip package 300 to a middle of chip package 300. In the middle of chip package 300, lead frame paddle or pad 312 may include a relatively large square or rectangular area. Other elements or regions may be placed upon such a square or rectangular area. A semiconductor die or device may be mounted on top of such a square or rectangular area.

Chip package 300 may include multiple pins or lead frame arms 302. A semiconductor die mounted onto lead frame paddle or pad 312 may be wire bonded to such lead frame arms. Chip package 300 may include a region 306 separating lead frame paddle or pad 312 from the rest of the interior of chip package 300. Region 306 may include a gap between the inner leads of chip package 300 and lead frame paddle or pad 306.

Chip package 300 may include a plating area 304. In one embodiment, plating area 304 may be implemented using silver. Plating area 304 may be formed on top of lead frame paddle or pad 312. A portion of a top or side of a semiconductor die or device mounted on top of lead frame paddle or pad 312 may be connected to a portion of plating area 304 using down bonding.

In one embodiment, plating area 304 may be formed in a ring around the perimeter of lead frame paddle or pad 312. The ring forming plating area 304 may leave a region 308 in the middle of plating area 304. In one embodiment, region 308 may be implemented as copper.

In one embodiment, a gap 310 or separation may be left or formed between an edge of plating area 304 and an edge of lead frame paddle or pad 312. Gap 310 may be illustrated by gaps 310A, 310B, 310C, 310D. Gap 310 may be coextensive around the perimeter of plating area 304. In a further embodiment, gap 310 may include exposed area of copper.

Gap 310 may facilitate silver areas for ground bonding. The size of gap 310 may be established through suitable experimentation, depending upon the plating area chosen, the size of the die, and other dimensions of the chip package. For example, gap 310 may be 3-20 mils (thousandths of an inch wide). In such an example, the silver area may be 3 mils from the edge of the lead frame to 20 mils away from the edge of the lead frame. The gap of copper area to make the silver area for ground bonding would need 3 mils minimum from edge of lead frame to 20 mils away from the edge of the lead frame.

FIG. 4 is a top-view of a chip package 400 with isolated silver or silver islands in the lead frame, according to embodiments of the present disclosure.

Chip package 400 may include a lead frame paddle or pad 412. Lead frame paddle or pad 412 may be implemented using any suitable metal, such as copper. Lead frame paddle or pad 412 may include four angled support arms extending from corners of chip package 400 to a middle of chip package 400. In the middle of chip package 400, lead frame paddle or pad 412 may include a relatively large square or rectangular area. Other elements or regions may be placed upon such a square or rectangular area. A semiconductor die or device may be mounted on top of such a square or rectangular area.

Chip package 400 may include multiple pins or lead frame arms 402. A semiconductor die or device mounted onto lead frame paddle or pad 412 may be wire bonded to such lead frame arms. Chip package 400 may include a region 406 separating lead frame paddle or pad 412 from the rest of the interior of chip package 400.

Chip package 400 may include plating areas 404. In one embodiment, plating areas 404 may be implemented using silver. Plating areas 404 may be formed on top of lead frame paddle or pad 412. A portion of a top or side of a semiconductor die or device mounted on top of lead frame paddle or pad 412 may be connected to a portion of a give one of plating areas 404 using down bonding.

In one embodiment, plating areas 404 may be formed in a ring around the perimeter of lead frame paddle or pad 412 with gaps between plating areas 404, yielding plating area islands. Although a particular number, size, and arrangement of plating areas 404A-404I are shown in FIG. 4, any suitable number and size of plating areas 404 may be used. In comparison with plating area 304, plating areas 404 may follow the footprint of plating area 304, albeit with gaps causing plating areas 404 to form plating area islands. Plating areas 404 may leave a region 408 in the middle. In one embodiment, region 408 may be implemented as copper.

In one embodiment, a gap 410 or separation may be left or formed between edges of each of plating areas 404 and an edge of lead frame paddle or pad 412. Gap 410 may be illustrated by gaps 410A, 410B, although such a gap may exist on all sides and perimeter around lead frame paddle or pad 412. Gap 410 may be coextensive around the outside edges of plating areas 404. In a further embodiment, gap 410 may include exposed area of copper.

Gap 410 may facilitate silver areas for ground bonding. The size of gap 410 may be established through suitable experimentation, depending upon the plating area chosen, the size of the die, and other dimensions of the chip package. For example, gap 410 may be 3-20 mils (thousandths of an inch wide). In such an example, the silver area may be 3 mils from the edge of the lead frame to 20 mils away from the edge of the lead frame. The gap of copper area to make the silver area for ground bonding would need 3 mils minimum from edge of lead frame to 20 mils away from the edge of the lead frame.

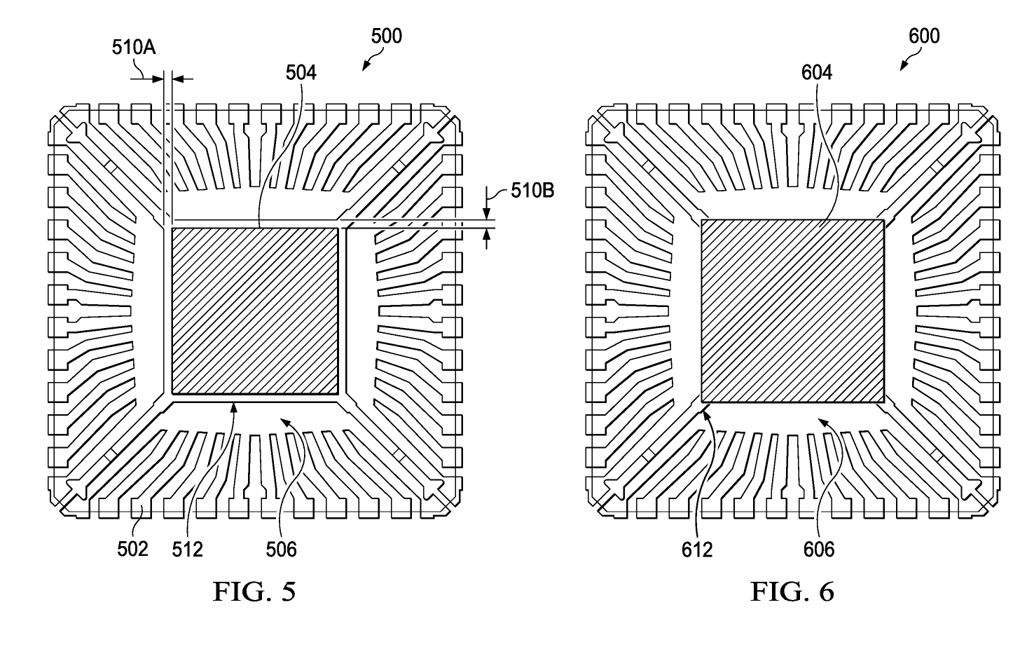

FIG. 5 is a top-view of a chip package 500 with rectangular silver plating area in the lead frame, according to embodiments of the present disclosure.

Chip package 500 may include a lead frame paddle or pad 512. Lead frame paddle or pad 512 may be implemented using any suitable metal, such as copper. Lead frame paddle or pad 512 may include four angled support arms extending from corners of chip package 500 to a middle of chip package 500. In the middle of chip package 500, lead frame paddle or pad 512 may include a relatively large square or rectangular area. Other elements or regions may be placed upon such a square or rectangular area. A semiconductor die or device may be mounted on top of such a square or rectangular area.

Chip package 500 may include multiple pins or lead frame arms 502. A semiconductor die or device mounted onto lead frame paddle or pad 512 may be wire bonded to such lead frame arms. Chip package 500 may include a region 506 separating lead frame paddle or pad 512 from the rest of the interior of chip package 500.

Chip package 500 may include a plating area 504. In one embodiment, plating area 504 may be implemented using silver. Plating area 504 may be formed on top of lead frame paddle or pad 512. A portion of a top or side of a semiconductor die or device mounted on top of lead frame paddle or pad 512 may be connected to a portion of a give one of plating areas 504 using down bonding.

In one embodiment, plating area 504 may be formed as a rectangle or square in the middle of lead frame paddle or pad 512. A semiconductor die or device may be mounted on top of plating area 504. Plating area 504 might not leave a region open in its middle.

In one embodiment, a gap 510 or separation may be left or formed between an edge of plating area 504 and an edge of lead frame paddle or pad 512. Gap 510 may be illustrated by gaps 510A, 510B, although such a gap may exist on all sides and perimeter around lead frame paddle or pad 512. Gap 510 may be coextensive around the perimeter of plating area 504. In a further embodiment, gap 510 may include exposed area of copper.

Gap 510 may facilitate silver areas for ground bonding. The size of gap 510 may be established through suitable experimentation, depending upon the plating area chosen, the size of the die, and other dimensions of the chip package. For example, gap 510 may be 3-20 mils (thousandths of an inch wide). In such an example, the silver area may be 3 mils from the edge of the lead frame to 20 mils away from the edge of the lead frame. The gap of copper area to make the silver area for ground bonding would need 3 mils minimum from edge of lead frame to 20 mils away from the edge of the lead frame.

FIG. 6 illustrates a chip package 600 without gaps between a plating area and an edge of a lead frame paddle.

Chip package 600 may include a lead frame paddle or pad 612. Furthermore, chip package 60 may include a plating area 604. No gap might exist between plating area 604 and an edge of lead frame paddle or pad 612. Plating area 604 may reach region 606. Although plating area 604 is shown as a rectangular, plating area 604 might include other arrangements or sizes wherein no gap exists between plating area 604 and an edge of lead frame paddle or pad 612. Thus, chip package 600 is implemented in a contrasting manner to the chip packages of FIGS. 3-5. Chip package 600 may be prone to delamination.

The present disclosure has been described in terms of one or more embodiments, and it should be appreciated that many equivalents, alternatives, variations, and modifications, aside from those expressly stated, are possible and within the scope of the disclosure. While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein.

1. An apparatus, comprising:
a lead frame paddle configured for mounting a semiconductor die;
a plating area formed on the lead frame paddle, the plating area configured to receive a down bond from a semiconductor die placed on the lead frame paddle; and
an exposed gap between an outer edge of the plating area and an outer edge of the lead frame paddle.

2. The apparatus of claim 1, wherein the plating area is formed of silver.

3. The apparatus of claim 1, wherein the exposed gap is formed of copper.

4. The apparatus of claim 1, wherein the plating area is formed as a ring around a perimeter of the lead frame paddle.

5. The apparatus of claim 1, further comprising a hollow portion within the plating area, wherein the hollow portion underlies the semiconductor die placed on the lead frame paddle.

6. The apparatus of claim 1, wherein the plating area is formed as a rectangle on the lead frame paddle, the rectangle coextensive with a perimeter of the lead frame paddle.

7. The apparatus of claim 1, further comprising a plurality of additional plating areas, wherein each additional plating area includes a further exposed gap between an outer edge of the additional plating area and the outer edge of the lead frame paddle.

8. An integrated circuit package, comprising:
a lead frame paddle;
a semiconductor die mounted on the lead frame paddle;
a plating area formed on the lead frame paddle, the plating area configured to receive a down bond from the semiconductor die mounted on the lead frame paddle; and
an exposed gap between an outer edge of the plating area and an outer edge of the lead frame paddle.

9. The integrated circuit package of claim 8, wherein the plating area is formed of silver.

10. The integrated circuit package of claim 8, wherein the exposed gap is formed of copper.

11. The integrated circuit package of claim 8, wherein the plating area is formed as a ring around a perimeter of the lead frame paddle.

12. The integrated circuit package of claim 8, further comprising a hollow portion within the plating area, wherein the hollow portion underlies the semiconductor die placed on the lead frame paddle.

13. The integrated circuit package of claim 8, wherein the plating area is formed as a rectangle on the lead frame paddle, the rectangle coextensive with a perimeter of the lead frame paddle.

14. The integrated circuit package of claim 8, further comprising a plurality of additional plating areas, wherein each additional plating area includes a further exposed gap between an outer edge of the additional plating area and the outer edge of the lead frame paddle.

15-20. (canceled)
